(19) United States
(12) Patent Application Publication
(10) Pub. No.: US 2013/0240256 A1
(43) Pub. Date: Sep. 19, 2013

(54) Method for Reducing Creep Corrosion

(71) Applicant: Timothy Von Werne, London (GB)

(72) Inventor: Timothy Von Werne, London (GB)

(21) Appl. No.: 13/885,119

(22) PCT Filed: Nov. 9, 2011
(86) PCT No.: PCT/GB11/01579

§ 371 Date: May 23, 2013

(30) Foreign Application Priority Data
Nov. 15, 2010 (GB) 1019302.7

(51) Int. Cl. H05K 3/28; H05K 1/09; H05K 1/03

(52) U.S. Cl. CPC H05K 3/282; H05K 1/032; H05K 1/09
USPC 174/257; 427/490; 174/258

(57) ABSTRACT

A method for reducing creep corrosion on a printed circuit board, the printed circuit board comprising a substrate, a plurality of electrically conductive tracks located on at least one surface of the substrate, a solder mask coating at least a first area of the plurality of electrically conductive tracks and a surface finish coating at least a second area of the plurality of electrically conductive tracks, the method comprising depositing by plasma-polymerization a fluorohydrocarbon onto at least part of the solder mask and at least part of the surface finish.

The present invention relates to a method for reducing creep corrosion on printed circuit boards, to coated printed circuit boards and to the use of particular polymers to reduce creep corrosion.

### BACKGROUND

Creep corrosion is a major problem in the electronics industry. Its increasing impact on the electronics industry is believed to be a result of a variety of factors, such as increased use of lead-free solder, miniaturization of components and exposure of electronic assemblies to increasingly harsh environments.

Creep corrosion is a mass transport process in which solid corrosion products, typically metal sulfides, migrate over a surface. It is a particular problem for printed circuit boards, where corrosion products may migrate onto solder mask surfaces on the printed circuit boards. This can result in short circuits between adjacent conductive tracks on the printed circuit boards and failure of the product.

The mechanism of creep corrosion is not well understood, but it is known to be a particular problem in high sulfur environments, where printed circuit boards may fail within six weeks. Moisture is also believed to be a contributory factor.

Various strategies for reducing creep corrosion have been attempted. Such strategies include: application of conformal coatings; cleaning of the printed circuit board following assembly; careful choice of the printed circuit board surface finish; and capping all non-soldered conductive tracks on the printed circuit board.

Each of these proposed solutions has been shown to fail in at least some cases and can actually make the situation worse. There is therefore a requirement in the electronics industry for a more reliable and efficient method for reducing creep corrosion.

### SUMMARY OF THE INVENTION

The present inventors have surprisingly found that a plasma-polymerized fluorohydrocarbon polymer can be used to reduce creep corrosion.

Thus, the present invention provides a method for reducing creep corrosion on a printed circuit board, the printed circuit board comprising a substrate, a plurality of electrically conductive tracks located on at least one surface of the substrate, a solder mask coating at least a first area of the plurality of electrically conductive tracks and a surface finish coating at least a second area of the plurality of electrically conductive tracks, the method comprising depositing by plasma-polymerization a fluorohydrocarbon onto at least part of the solder mask and at least part of the surface finish.

The invention further provides a coated printed circuit board obtainable by the method of the invention.

The invention further provides a coated printed circuit board comprising a substrate, a plurality of electrically conductive tracks located on at least one surface of the substrate, a solder mask coating at least a first area of the plurality of electrically conductive tracks, a surface finish coating at least a second area of the plurality of electrically conductive tracks, and a plasma-polymerized fluorohydrocarbon coating on at least part of the solder mask and at least part of the surface finish.

The invention further provides use of a plasma-polymerized fluorohydrocarbon to reduce creep corrosion of a printed circuit board, the printed circuit board comprising a substrate, a plurality of electrically conductive tracks located on at least one surface of the substrate, a solder mask coating at least a first area of the plurality of electrically conductive tracks and a surface finish coating at least a second area of the plurality of electrically conductive tracks.

### DESCRIPTION OF THE FIGURES

FIG. 1 shows a portion of the printed circuit board of Example 1, after 7 days of the sulfur clay test. Very little creep corrosion is visible.

FIG. 2 shows a portion of the printed circuit board of Example 2, after 7 days of the sulfur clay test. Very little creep corrosion is visible.

FIG. 3 shows a portion of the printed circuit board of Example 3, after 7 days of the sulfur clay test. Very little creep corrosion is visible.

FIG. 4 shows a portion of the printed circuit board of Example 4, after 7 days of the sulfur clay test. Very little creep corrosion is visible.

FIG. 5 shows a portion of the printed circuit board of Example 5, after 7 days of the sulfur clay test. Very little creep corrosion is visible.

FIG. 6 shows a portion of the printed circuit board of Example 6, after 7 days of the sulfur clay test. No creep corrosion is visible.

FIG. 7 shows a portion of the printed circuit board of Example 7, after 7 days of the sulfur clay test. Very little creep corrosion is visible.

FIG. 8 shows a portion of the printed circuit board of Comparative Example 1, after 7 days of the sulfur clay test. Extensive creep corrosion is visible.

FIG. 9 shows a portion of the printed circuit board of Comparative Example 2, after 7 days of the sulfur clay test. Extensive creep corrosion is visible.

FIG. 10 shows a portion of the printed circuit board of Comparative Example 3, after 7 days of the sulfur clay test. Extensive creep corrosion is visible.

FIG. 11 shows a portion of the printed circuit board of Comparative Example 4, after 7 days of the sulfur clay test. Extensive creep corrosion is visible.

FIG. 12 shows a cross-section of an example of a printed circuit board prior to coating by the method of the invention.

FIG. 13 shows a cross-section of an example of a coated printed circuit board.

### DETAILED DESCRIPTION OF THE INVENTION

An example method of the present invention involves depositing by plasma-polymerization a plasma-polymerized fluorohydrocarbon onto a printed circuit board comprising a substrate, a plurality of electrically conductive tracks located on at least one surface of the substrate, a solder mask coating at least a first area of the plurality of electrically conductive tracks and a surface finish coating at least a second area of the plurality of electrically conductive tracks.

In particular, the example method may involve depositing the plasma-polymerized fluorohydrocarbon onto at least part of the solder mask, at least part of the surface finish and at least a third area of the plurality of electrically conductive tracks which is not coated with solder mask or surface finish.

Typically the plasma-polymerized fluorohydrocarbon is deposited onto more than 75%, and preferably more than 90%, of the surface area of the solder mask. The plasma-polymerized fluorohydrocarbon may be deposited onto substantially all of the surface area of the solder mask

Typically the plasma-polymerized fluorohydrocarbon is deposited onto more than 75%, and preferably more than 90%, of the surface area of the surface finish. The plasma-polymerized fluorohydrocarbon may be deposited onto substantially all of the surface area of the surface finish.

The plurality of electrically conductive tracks may comprise a third area which is not coated with solder mask or surface finish. Such an area which is not coated with solder mask or surface finish is generally a defect, normally in the surface finish or solder mask. It is generally preferably for areas of the electrically conductive tracks which are not coated with solder mask or surface finish to be absent. If a third area of plurality of electrically conductive tracks which is not coated with solder mask or surface finish is present, typically the plasma-polymerized fluorohydrocarbon is deposited onto at least part of the third area. Preferably the plasma-polymerized fluorohydrocarbon is deposited onto more than 75%, and more preferably more than 90%, of the surface area of the plurality of electrically conductive tracks which is not coated with solder mask or surface finish or attached to the substrate. The plasma-polymerized fluorohydrocarbon may be deposited onto substantially all of the surface area of the plurality of electrically conductive tracks which is not coated with solder mask or surface finish or attached to the substrate.

Generally, the plasma-polymerized fluorohydrocarbon is also deposited onto to at least part of the substrate which is not covered by the plurality of conductive tracks. Typically the plasma-polymerized fluorohydrocarbon is deposited onto more than 75%, and preferably more than 90%, of the surface area of the substrate which is not covered by the plurality of conductive tracks.

Plasma-polymerized polymers are a unique class of polymers which cannot be prepared by traditional polymerization methods. Plasma-polymerized polymers have a highly disordered structure and are generally highly crosslinked, contain random branching and retain some reactive sites. Plasma-polymerized polymers are thus chemically distinct from polymers prepared by traditional polymerization methods known to those skilled in the art. These chemical and physical distinctions are well known and are described, for example in Plasma Polymer Films, Hynek Biederman, Imperial College Press 2004.

A plasma-polymerized fluorohydrocarbon is typically a straight and/or branched polymer which optionally contains cyclic moieties. Said cyclic moieties are preferably alicyclic rings or aromatic rings, more preferably aromatic rings. Preferably the plasma-polymerized fluorohydrocarbon does not contain any cyclic moieties. Preferably the plasma-polymerized fluorohydrocarbon is a branched polymer.

The plasma-polymerized fluorohydrocarbon optionally contains heteroatoms selected from N, O, Si and P. Preferably, however, the plasma-polymerized fluorohydrocarbon contains no N, O, Si and P heteroatoms.

An oxygen-containing plasma-polymerized fluorohydrocarbon preferably comprises carbonyl moieties, more preferably ester and/or amide moieties. A preferred class of oxygen-containing plasma-polymerized fluorohydrocarbon polymers are plasma-polymerized fluoroacrylate polymers.

A nitrogen containing plasma-polymerized fluorohydrocarbon preferably comprises nitro, amine, amide, imidazole, diazole, trizole and/or tetraazole moieties

Preferably the plasma-polymerized fluorohydrocarbon is branched and contains no heteroatoms.

The plasma-polymerized fluorohydrocarbon used in the present invention may be obtainable by a plasma-polymerization technique. Plasma-polymerization is generally an effective technique for depositing thin film coatings. Generally plasma-polymerization provides excellent quality coatings, because the polymerization reactions occur in situ. As a result, the plasma-polymerized polymer is generally deposited in small recesses, under components and in vias that would not be accessible by normal liquid coating techniques in certain situations.

Plasma deposition may be carried out in a reactor that generates a gas plasma which comprises ionised gaseous ions, electrons, atoms, and/or neutral species. A reactor may comprise a chamber, a vacuum system, and one or more energy sources, although any suitable type of reactor configured to generate a gas plasma may be used. The energy source may include any suitable device configured to convert one or more materials to a gas plasma. Preferably the energy source comprises a heater, radio frequency (RF) generator, and/or microwave generator.

In an example method of the invention, a printed circuit board may be placed in the chamber of a reactor and a vacuum system may be used to pump the chamber down to pressures in the range of 10⁻³ to 10 mbar. One or more materials may then be pumped into the chamber and an energy source may generate a stable gas plasma. One or more precursor compounds may then be introduced, as gases and/or liquids, into the gas plasma in the chamber. When introduced into the gas plasma, the precursor compounds may be ionized and/or decomposed to generate a range of active species in the plasma that polymerize to generate the polymer coating. Pulsed plasma systems may also be used.

A plasma-polymerized fluorohydrocarbon is preferably obtained by plasma polymerization of one or more precursor compounds which are hydrocarbon materials comprising fluorine atoms. Preferred hydrocarbon materials comprising fluorine atoms are perfluoroalkanes, perfluoroalkenes, perfluoroalkanes, fluoroalkanes, fluoroalkenes, fluoroalkynes. Examples include CF₄, C₂F₄, C₂F₆, C₃F₆ C₃F₈ and C₄F₈.

The exact nature and composition of the plasma-polymerized fluorohydrocarbon coating typically depends on one or more of the following conditions (i) the plasma gas selected; (ii) the particular precursor compound(s) used; (iii) the amount of precursor compound(s) (which may be determined by the combination of the pressure of precursor compound(s) and the flow rate); (iv) the ratio of precursor compound(s); (v) the sequence of precursor compound(s); (vi) the plasma pressure; (vii) the plasma drive frequency; (viii) the pulse width timing; (ix) the coating time; (x) the plasma power (including the peak and/or average plasma power); (xi) the chamber electrode arrangement; and/or (xii) the preparation of the incoming assembly.

Typically the plasma drive frequency is 1 kHz to 1 GHz. Typically the plasma power is 500 to 10000 W. Typically the mass flow rate is 5 to 2000 sccm. Typically the operating pressure is 10 to 500 mTorr. Typically the coating time is 10 seconds to 20 minutes.

However, as a skilled person will appreciate, the preferred conditions will be dependent on the size and geometry of the plasma chamber. Thus, depending on the specific plasma chamber that is being used, it may be beneficial for the skilled person to modify the operating conditions.

The plasma-polymerized fluorohydrocarbon coating used in the present invention typically has a mean-average thickness of 1 nm to 10 μm, preferably 1 nm to 5 μm, more preferably 5 nm to 500 nm, more preferably 10 nm to 100 nm, and more preferably 25 nm to 75 nm, for example about 50 nm. The thickness of the coating may be substantially uniform or may vary from point to point.

The printed circuit board coated in the method of the present invention comprises a substrate, a plurality of electrically conductive tracks located on at least one surface of the substrate, a solder mask coating at least a first area of the plurality of electrically conductive tracks and a surface finish coating at least a second area of the plurality of electrically conductive tracks. The printed circuit boards generally do not initially have any electrical components attached thereto.

A person skilled in the art can select suitable shapes and configurations for the plurality of electrically conductive tracks, depending on the end-purpose of the printed circuit board. Typically, an electrically conductive track is attached to the surface of the substrate along its entire length. Alternatively, an electrically conductive track may be attached to the substrate at two or more points. For example, an electrically conductive track may be a copper wire attached to the substrate at two or more points, but not along its entire length.

An electrically conductive track is typically formed on a substrate using any suitable method known to those skilled in the art. In a preferred method, electrically conductive tracks are formed on a substrate using a “subtractive” technique. Typically in this method, a layer of electrically conductive material is bonded to a surface of the substrate and then the unwanted portions of the electrically conductive material are removed, leaving the desired conductive tracks. The unwanted portions of the electrically conductive material are typically removed from the substrate by chemical etching, photo-etching and/or milling. In an alternative method, electrically conductive tracks are formed on the substrate using an “additive” technique such as, for example, electroplating, deposition using a reverse mask, and/or any geometrically controlled deposition process.

An electrically conductive track typically comprises gold, tungsten, copper, silver and/or aluminium, preferably gold, tungsten, copper, silver and/or aluminium, more preferably copper. An electrically conductive track may consist essentially or consist of copper.

The substrate of the printed circuit board generally comprises an electrically insulating material. The substrate typically comprises any suitable insulating material that prevents the substrate from shorting the circuit of the printed circuit board.

A substrate preferably comprises an epoxy laminate material, a synthetic resin bonded paper, an epoxy resin bonded glass fabric (ERBGH), a composite epoxy material (CEM), PTFE (Teflon), or other polymer materials, phenolic cotton paper, silicon, glass, ceramic, paper, cardboard, natural and/or synthetic wood based materials, and/or other suitable textiles. The substrate optionally further comprises a flame retardant material, typically Flame Retardant 2 (FR-2) and/or Flame Retardant 4 (FR-4). The substrate may comprise a single layer of an insulating material or multiple layers of the same or different insulating materials.

A solder mask may coat at least a first area of the electrically conductive tracks. A solder mask is generally intended to prevent solder from bridging the electrically conductive tracks, thereby preventing short circuits. Typically the solder mask is an epoxy solder mask, a liquid photoimageable solder mask (LPSM) ink or a dry film photoimageable solder mask (DFSM). Such solder masks can readily be applied to the printed circuit board by techniques known to those skilled in the art.

Preferably the solder mask coating at least a first area of the plurality of electrically conductive tracks additionally coats an area of the substrate. In that case, the solder mask may overhang the edge of at least part of the electrically conductive tracks and covers an adjacent area of the substrate. Creep corrosion is generally particularly aggressive in this situation. Preferably, the plasma-polymerized fluorohydrocarbon is deposited onto the portion of the solder mask that additionally coats an area of the substrate or overhangs the edge of at least part of the electrically conductive tracks and covers an adjacent area of the substrate.

A surface finish may coat at least a second area of the electrically conductive tracks. The surface finish is typically immersion silver (ImAg), electroless nickel/immersion gold (ENIG), organic solderability preservative (OSP), electroless nickel/electroless palladium/immersion gold (ENEPIG) or immersion tin (ImSn). Preferably the surface finish is immersion silver (ImAg) or organic solderability preservative (OSP), more preferably immersion silver (ImAg).

Optionally, an example method of the invention may additionally comprise, after deposition of the plasma-polymerized fluorohydrocarbon, connecting at least one electrical component to at least one electrically conductive track. The at least one electrical component may be connected to the at least one conductive track through the plasma polymerised fluorohydrocarbon.

Preferably, the electrical component is connected to the at least one electrically conductive track via a solder joint, a weld joint or a wire-bond joint. If the electrical component has been connected through the plasma polymerized fluorohydrocarbon, preferably the solder joint, weld joint or wire-bond joint abuts the plasma polymerised fluorohydrocarbon. It is possible to solder, weld or wire bond through the plasma polymerized fluorohydrocarbon, as described in WO 2008/102113 (the content of which is incorporated herein by reference).

An electrical component may be any suitable circuit element of printed circuit board. Preferably, an electrical component is a resistor, capacitor, transistor, diode, amplifier, antenna or oscillator. Any suitable number and/or combination of electrical components may be connected to the electrical assembly.

After the coated printed circuit board has been assembled, that is to say all necessary electrical components have been connected, it may be desired to deposit by plasma-polymerization an additional coating of plasma-polymerized fluorohydrocarbon. The additional coating may be a conformal coating. This can generally provide additional environmental and physical protection.

The present invention also relates to a coated printed circuit board. Example coated printed circuit boards may be prepared methods described above. Such coated printed circuit boards may comprise a substrate, a plurality of electrically conductive tracks located on at least one surface of the substrate, a solder mask coating at least a first area of the plurality of electrically conductive tracks, a surface finish coating at least a second area of the plurality of electrically conductive tracks, and a plasma-polymerized fluorohydrocarbon coating on at least part of the solder mask, at least part of the surface finish and optionally at least a third area of the plurality of electrically conductive tracks which is not coated with solder mask or surface finish. The substrate, electrically conductive tracks, solder mask, surface finish and plasma-polymerized fluorohydrocarbon may be as defined above.

Example coated printed circuit boards may further comprise an electrical component connected to at least one electrically conductive track through the plasma-polymerized fluorohydrocarbon coating. The electrical component and connection to the electrically conductive track may be as defined above.

The present invention also relates to use of a plasma-polymerized fluorohydrocarbon to reduce creep corrosion of a printed circuit board which may be as defined above.

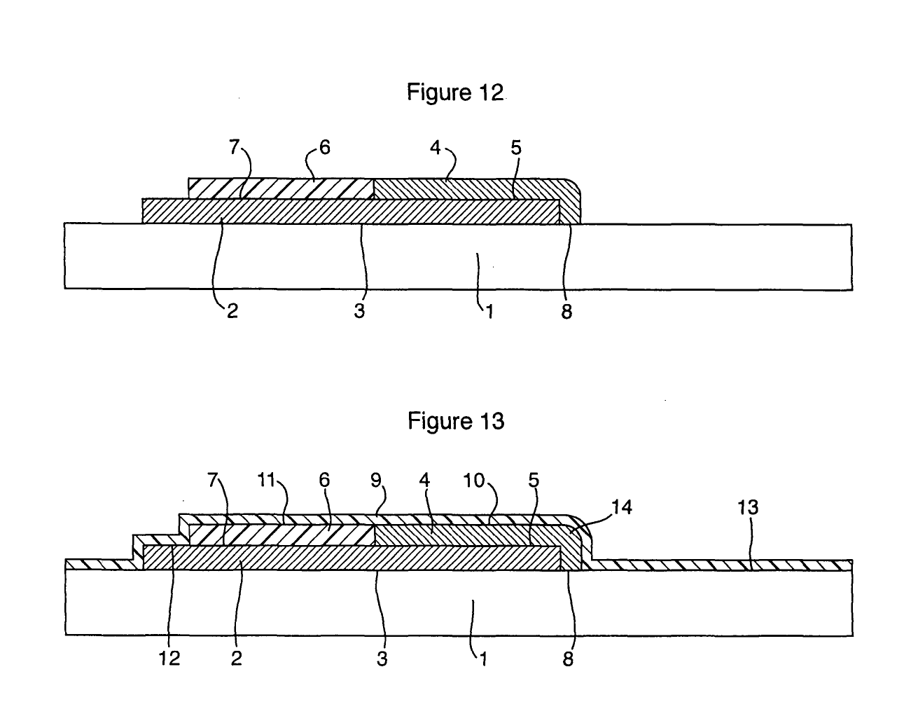

Aspects of the invention will now be described with reference to the embodiment shown in FIGS. 12 and 13, in which like reference numerals refer to the same or similar components.

FIG. 12 shows an example of printed circuit board prior to coating comprising a substrate 1, a plurality of electrically conductive tracks 2 located on at least one surface 3 of the substrate, a solder mask 4 coating at least a first area 5 of the plurality of electrically conductive tracks and a surface finish 6 coating at least a second area 7 of the plurality of electrically conductive tracks. The solder mask optionally additionally coats an area 8 of the substrate.

FIG. 13 shows an example of a coated printed circuit board comprising a substrate 1, a plurality of electrically conductive tracks 2 located on at least one surface 3 of the substrate, a solder mask 4 coating at least a first area 5 of the plurality of electrically conductive tracks, a surface finish 6 coating at least a second area 7 of the plurality of electrically conductive tracks, and a plasma-polymerized fluorohydrocarbon coating 9 on at least part 10 of the solder mask, at least part 11 of the surface finish and optionally at least a third area 12 of the plurality of electrically conductive tracks which is not coated with solder mask or surface finish. The plasma-polymerized fluorohydrocarbon also optionally coats at least part 13 of the substrate.

Aspects of the invention will now be described with reference to the Examples

### EXAMPLES

### Sulfur Clay Test Method

The sulfur clay test method is a technique for simulating conditions, such as a clay modelling studio, where creep corrosion is very aggressive. This method is a well-known technique in the art for assessing the effects of creep corrosion and uses a sulfur bearing clay as a source of sulfur compounds (see, for example, Creep corrosion on lead-free printed circuit boards in high sulfur environments, Randy Schueller, Published in SMTA Int'l Proceedings, Orlando, Fla., October 2007).

Plasteline sulphur bearing modelling clay (marketed by Chavant) was wetted with water and heated inside a container. Test printed circuit boards were immediately placed in the container with the hot clay. Sulfur compounds from the clay condensed onto the surfaces of the printed circuit boards and created suitable conditions for creep corrosion.

### Coating A

A printed circuit board was introduced to a plasma chamber. The chamber was pumped down to an operating pressure of 50 mTorr and C₃F₆ gas was introduced at a flow rate of 100 sccm. The gas was allowed to flow through the chamber for 30 seconds and then the plasma generator was switched on at a frequency of 13.56 MHz and a power of 2.4 kW. The printed circuit board was exposed to the active plasma for a time period of 7 minutes, after which the plasma generator was switched off, the chamber brought back to atmospheric pressure, and the coated printed circuit board removed from the chamber.

### Coating B

A printed circuit board was introduced to a plasma chamber. The chamber was pumped down to an operating pressure of 70 mTorr and C₃F₆ gas was introduced at a flow rate of 750 sccm. The gas was allowed to flow through the chamber for 30 seconds and then the plasma generator was switched on at a frequency of 40 KHz and a power of 7 kW. The printed circuit board was exposed to the active plasma for a time period of 10 minutes, after which the plasma generator was switched off, the chamber brought back to atmospheric pressure, and the coated printed circuit board removed from the chamber.

### Coating C

A printed circuit board was introduced to a plasma chamber. The chamber was pumped down to an operating pressure of 60 mTorr and C₃F₆ gas was introduced at a flow rate of 750 sccm. A second gas, helium, was added to the chamber at a flow rate of 100 sccm through a second mass flow controller. The gas mixture was allowed to flow through the chamber for 30 seconds and then the plasma generator was switched on at a frequency of 40 KHz and a power of 7 kW. The printed circuit board was exposed to the active plasma for a time period of 10 minutes, after which the plasma generator was switched off, the chamber brought back to atmospheric pressure, and the coated printed circuit board removed from the chamber.

### Evaluation of Test Printed Circuit Boards

Starting from standard blank printed circuit boards with copper tracks and solder mask, a series of test printed circuit boards were prepared. These had the features set out in Tables 1 and 2 below.

In particular, a surface finish of immersion silver (ImAg) or organic solderability preservative (OSP) was optionally applied to each printed circuit board. Coating A was then optionally deposited onto the printed circuit board. Next, electrical components were optionally connected to the printed circuit board. Finally, an overcoat of Coating A, Coating B or Coating C was optionally applied over the printed circuit board and electrical components.

TABLE 1

| Exam- | Surface | Creep corrosion | Components | | Evalua- |
|---|---|---|---|---|---|
| ple | finish | reduction coating | in situ | Overcoat | tion |
| 1 | No | Coating A | No | No | + |
| 2 | No | Coating A | Yes | No | + |
| 3 | No | Coating A | Yes | Coating A | + |
| 4 | ImAg | Coating A | Yes | No | + |
| 5 | No | Coating A | Yes | Coating B | + |
| 6 | No | Coating A | Yes | Coating C | ++ |
| 7 | OSP | Coating A | Yes | No | + |

TABLE 2

| | | Creep | | | |
|---|---|---|---|---|---|
| | | corrosion | | | |
| Comparative | Surface | reduction | Components | | |
| Example | finish | coating | in situ | Overcoat | Evaluation |
| 1 | ImAg | No | No | No | −− |
| 2 | ImAg | No | Yes | No | −− |
| 3 | ImAg | No | Yes | Coating A | −− |
| 4 | OSP | No | Yes | No | −− |

The printed circuit boards of Examples 1 to 7 and Comparative Examples 1 to 4 were subjected to the sulfur clay test for 7 days. After 7 days, the printed circuit boards were removed and examined for the presence of creep corrosion.

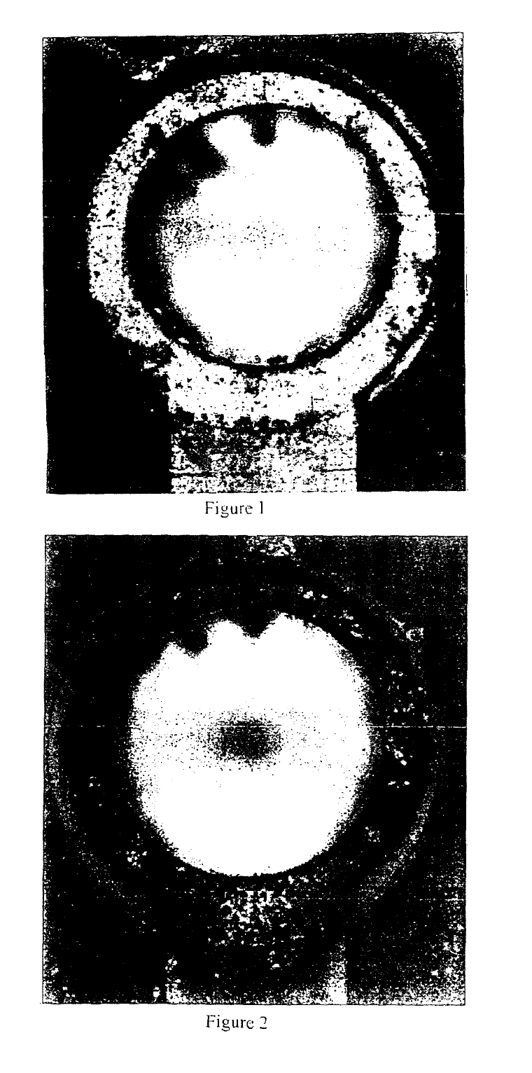

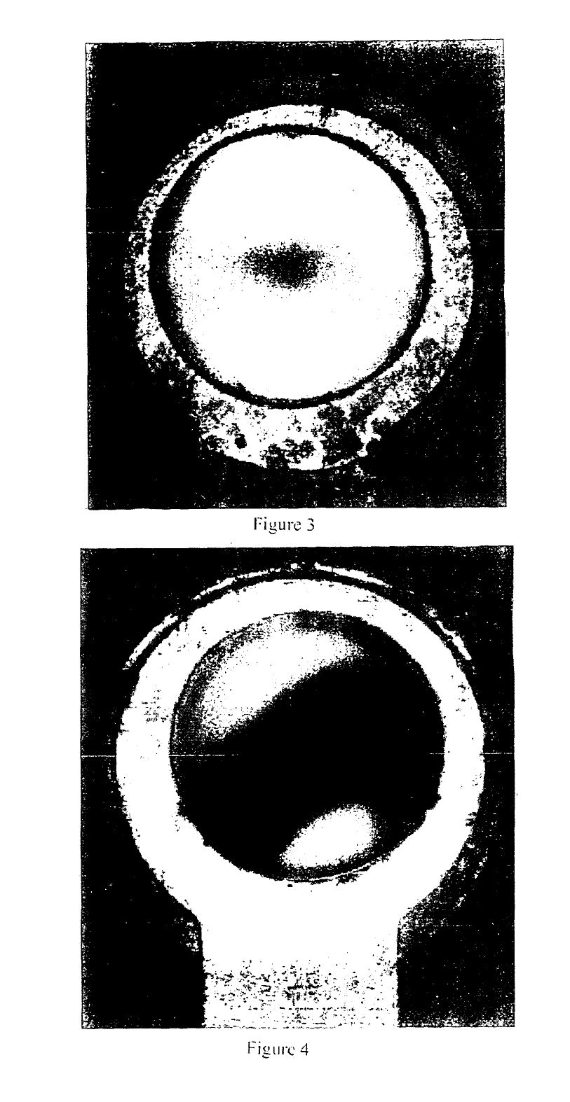

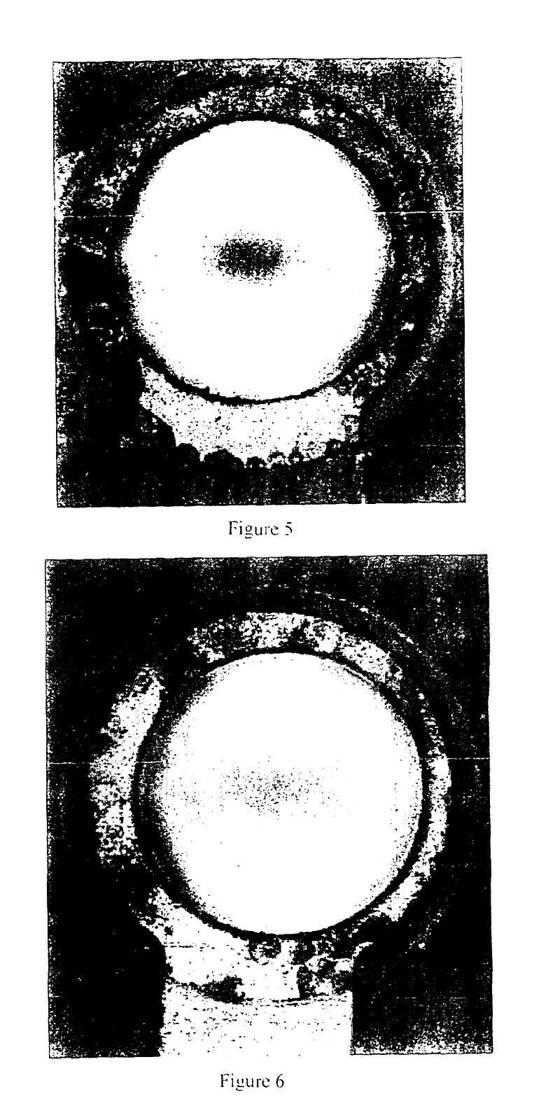

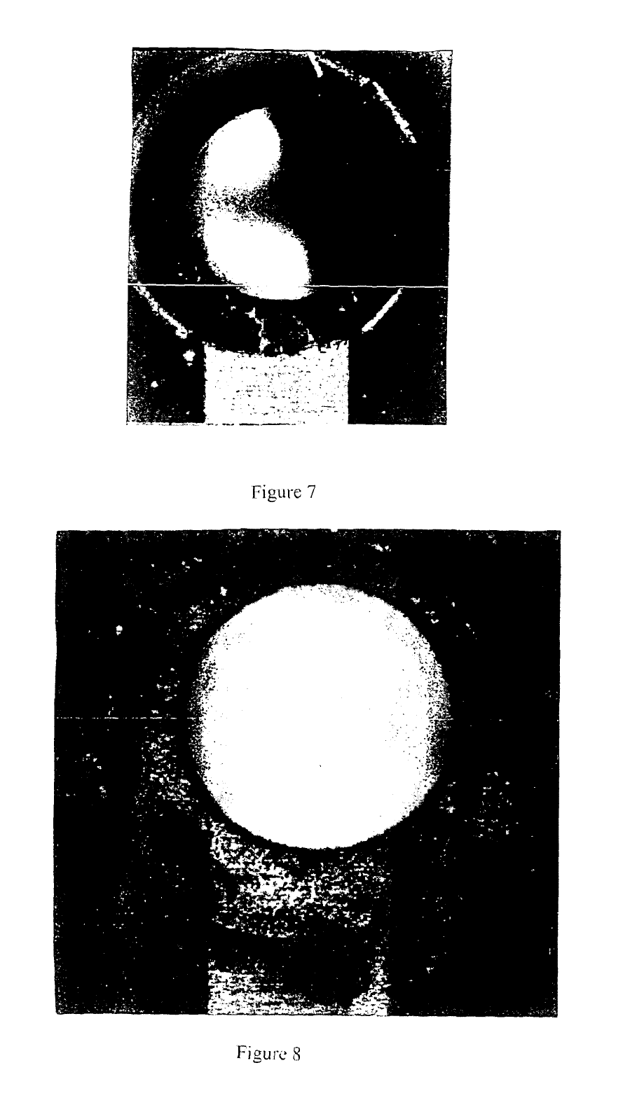

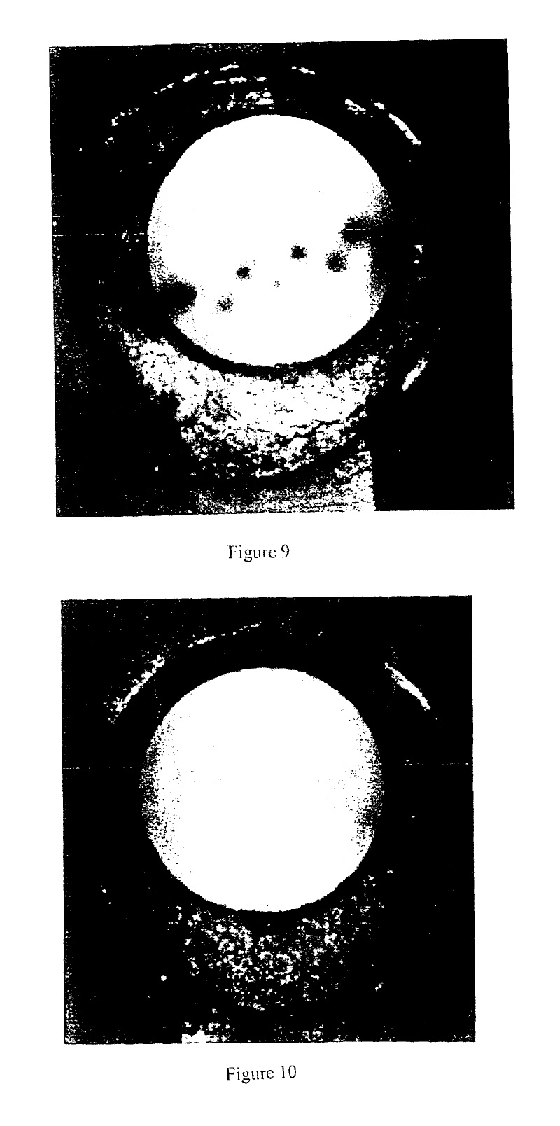

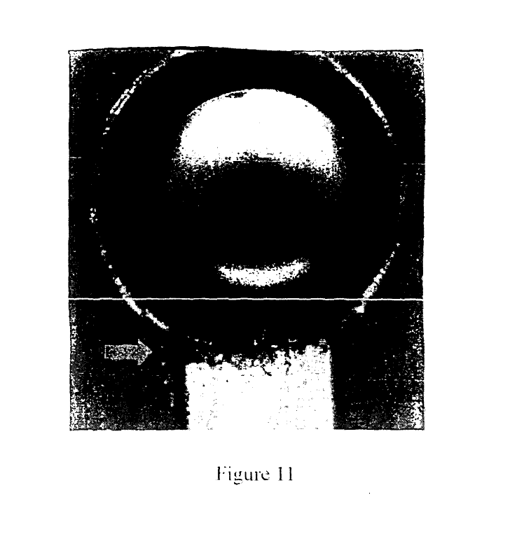

FIGS. 1 to 11 show equivalent portions of the printed circuit boards of Example 1 to 7 and Comparative Examples 1 to 4 respectively. As shown in Tables 1 and 2, the printed circuit boards were categorised as follows:
No creep corrosion (++)
Low levels creep corrosion (+)
High levels of creep corrosion (−)

### CONCLUSIONS

The application by plasma-polymerization of a fluorohydrocarbon onto a printed circuit board prior to addition of electronic components significantly reduced the incidence of creep corrosion.

1.-18. (canceled)

19. A method for reducing creep corrosion on a printed circuit board comprising:
selecting a printed circuit board comprising:
a substrate;
a plurality of electrically conductive tracks located on at least one surface of the substrate;
a solder mask coating at least a first area of the plurality of electrically conductive tracks; and
a surface finish coating at least a second area of the plurality of electrically conductive tracks; and
depositing by plasma-polymerization a fluorohydrocarbon onto at least part of the solder mask and at least part of the surface finish.

20. The method of claim 19, wherein the surface finish is selected from the group consisting of immersion silver (ImAg), electroless nickel/immersion gold (ENIG), organic solderability preservative (OSP), electroless nickel/electroless palladium/immersion gold (ENEPIG), and immersion tin (ImSn).

21. The method of claim 19, wherein the surface finish is immersion silver (ImAg).

22. The method of claim 19, wherein the fluorohydrocarbon is selected from the group consisting of CF₄, C₂F₄, C₂F₆, C₃F₈, and C₄F₈.

23. The method of claim 19, wherein the solder mask is selected from the group consisting of epoxy solder mask, liquid photoimageable solder mask ink, and dry film photoimageable solder mask.

24. The method of claim 19, wherein the solder mask additionally coats an area of the substrate.

25. The method of claim 19, further comprising:
after depositing the plasma-polymerized fluorohydrocarbon, connecting at least one electrical component to at least one electrically conductive track.

26. The method of claim 25, further comprising:
after connecting the at least one electrical component to the at least one electrically conductive track, depositing by plasma-polymerization an additional coating comprising a fluorohydrocarbon.

27. The method of claim 26, wherein the additional coating comprising the plasma-polymerized fluorohydrocarbon conformally coats the printed circuit board and at least one electrical component.

28. The method of claim 19, further comprising:
depositing by plasma-polymerization a fluorohydrocarbon onto at least a third area of the plurality of electrically conductive tracks that is not coated with solder mask or surface finish.

29. The method of claim 19, wherein the plurality of electrically conductive tracks comprise copper.

30. An apparatus comprising:
a printed circuit board comprising:
a substrate;
a plurality of electrically conductive tracks located on at least one surface of the substrate;
a solder mask coating at least a first area of the plurality of electrically conductive tracks;
a surface finish coating at least a second area of the plurality of electrically conductive tracks; and
a plasma-polymerized fluorohydrocarbon coating on at least part of the solder mask and at least part of the surface finish.

31. The apparatus of claim 30, wherein the surface finish is selected from the group consisting of immersion silver (ImAg), electroless nickel/immersion gold (ENIG), organic solderability preservative (OSP), electroless nickel/electroless palladium/immersion gold (ENEPIG), and immersion tin (ImSn).

32. The apparatus of claim 30, wherein the surface finish is immersion silver (ImAg).

33. The apparatus of claim 30, wherein the fluorohydrocarbon is selected from the group consisting of CF₄, C₂F₄, C₂F₆, C₃F₈, and C₄F₈.

34. The apparatus of claim 30, wherein the solder mask is selected from the group consisting of epoxy solder mask, liquid photoimageable solder mask ink, and dry film photoimageable solder mask.

35. The apparatus of claim 30, wherein the solder mask additionally coats an area of the substrate.

36. The apparatus of claim 30, further comprising at least one electrical component connected to at least one electrically conductive track through the plasma-polymerized fluorohydrocarbon coating.

37. The apparatus of claim 30, further comprising an additional coating of a plasma-polymerized fluorohydrocarbon conformally coating the printed circuit board and at least one electrical component.

38. The apparatus of claim 30, further comprising a plasma-polymerized fluorohydrocarbon coating on at least a third area of the plurality of electrically conductive tracks which is not coated with solder mask or surface finish.

39. The apparatus of claim 30 wherein the plurality of electrically conductive tracks comprise copper.

40. A coated printed circuit board prepared by a process comprising the steps of:
selecting a printed circuit board comprising:
a substrate;
a plurality of electrically conductive tracks located on at least one surface of the substrate;
a solder mask coating at least a first area of the plurality of electrically conductive tracks; and
a surface finish coating at least a second area of the plurality of electrically conductive tracks; and
depositing by plasma-polymerization a fluorohydrocarbon onto at least part of the solder mask and at least part of the surface finish.
